(19) United States
(12) Patent Application Publication
(10) Pub. No.: US 2010/0012365 A1
(43) Pub. Date: Jan. 21, 2010

(54) PRINTED CIRCUIT BOARD

(75) Inventors: Po-Chuan HSIEH, Tu-Cheng (TW); Shou-Kuo HSU, Tu-Cheng (TW); Yu-Chang PAI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/205,167

(22) Filed: Sep. 5, 2008

(30) Foreign Application Priority Data
Jul. 21, 2008 (CN) 200810302873.2

(51) Int. Cl. H05K 1/11; H05K 3/30

(52) U.S. Cl. 174/261; 29/832

(57) ABSTRACT

A printed circuit board includes first and second connector pads, first and second connection components, and first, second, and third transmission lines. A method for supporting two connectors on the printed circuit board is also provided. The printed circuit board is capable of supporting different types of connectors by setting the first and second connection components on the printed circuit board.

### BACKGROUND

1. Field of the Invention

The present invention relates to printed circuit boards, and particularly, to a printed circuit board that supports different connectors.

2. Description of Related Art

A typical personal computer includes a motherboard, memory modules, and peripheral accessories. The number of connectors on a motherboard varies according to user requirements. For example, a PCI express chip can support one PCI-Express×8 connector, or two PCI-Express×4 connectors. However, the PCI express chip can support only one type of PCI-Express connector at a time. If the PCI-Express connector does not match the PCI express chip, the layout of the motherboard must be changed accordingly. Thus, the cost for producing motherboards is high.

What is needed is a printed circuit board that overcomes the above-described shortcoming.

### BRIEF DESCRIPTION OF THE DRAWINGS

FIG. 1 is a schematic diagram of one embodiment of a printed circuit board, the printed circuit board includes a chip connected to a connector pad; and

FIG. 2 is similar to FIG. 1, except that the chip is connected to another connector pad.

### DETAILED DESCRIPTION

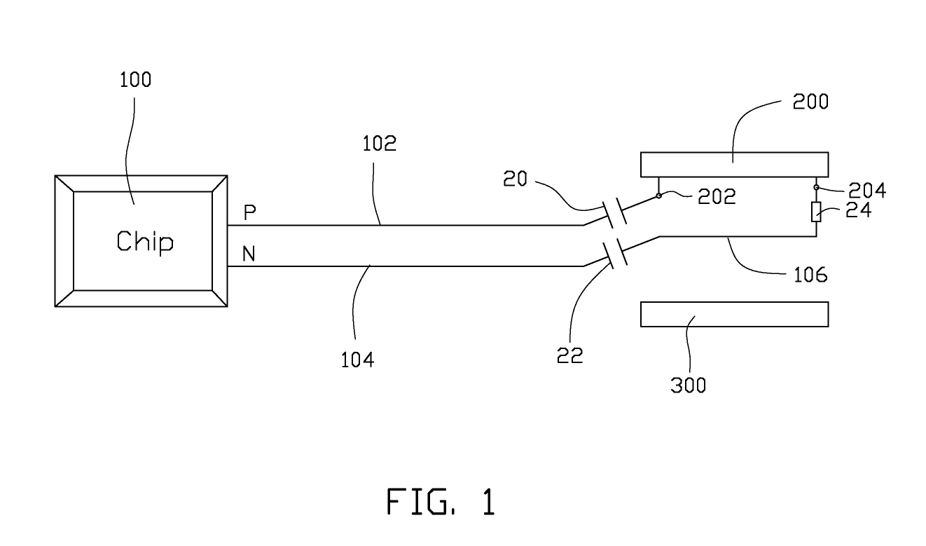

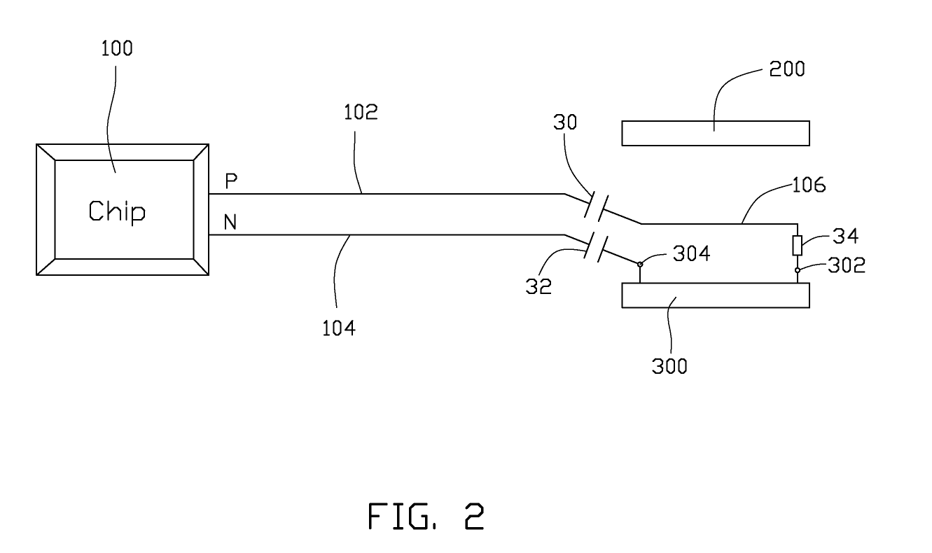

Referring to FIGS. 1 and 2, one embodiment of a printed circuit board includes a chip 100, a plurality of connection components 20, 22, 24, 30, 32, and 34, two connector pads 200 and 300, and three transmission lines 102, 104, and 106. The chip 100 includes an output terminal P and an output terminal N. The connector pad 200 includes two input terminals 202 and 204. The connector pad 300 includes two input terminals 302 and 304. The connector pads 200 and 300 are configured to be installed with different connectors.

If a connector is installed on the connector pad 200 as shown in FIG. 1, the chip 100 communicates with the installed connector. The output terminal P is connected to the input terminal 202 via the transmission line 102 and the connection component 20. The output terminal N is connected to the input terminal 204 via the transmission line 104, the connection component 22, the transmission line 106, and the connection component 24. The connector pad 300 is idle. The chip 100 sends high speed differential signals from the output terminals P and N to the connector pad 200 via the transmission lines 102, 104, and the connection components 20, 22.

If another connector is installed on the connector pad 300 as shown in FIG. 2, the chip 100 communicates with the installed connector, and the connection components 20, 22 and 24 may be removed from the printed circuit board. The output terminal P is connected to the input terminal 302 via the transmission line 102, the connection component 30, the transmission line 106, and the connection component 34. The output terminal N is connected to the input terminal 304 via the transmission line 104 and the connection component 32. The connector pad 200 is idle. The chip 100 sends high speed differential signals from the output terminals P and N to the connector pad 300 via the transmission lines 102, 104, and the connection components 30, 32.

In one embodiment, the connection components 20, 22, 30, and 32 are capacitors capable of filtering out interference signals thereby improving signal transmission quality. The connection components 24 and 34 may be zero ohm resistors to reduce the loss of signal transmission. In another embodiment, the connection components 20, 22, 30, and 32 may be filters. In yet another embodiment, the connection components 24 and 34 may be omitted, such that if a connector is installed on the connector pad 200, then the transmission line 106 is directly connected to the input terminal 204. If another connector is installed on the connector pad 300, the transmission line 106 is directly connected to the input terminal 302.

The printed circuit board is capable of supporting different types of connectors by selectively setting the connection components 20, 22, 24, 30, 32, and 34 on the printed circuit board without changing the wiring of the transmission lines 102, 104, and 106 or making new holes in the printed circuit board.

The foregoing description of the embodiments has been presented only for the purposes of illustration and description and is not intended to be exhaustive or to limit the embodiments to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the embodiments pertain without departing from its spirit and scope. Accordingly, the scope of the embodiments is defined by the appended claims rather than the foregoing description and the embodiments described therein.

What is claimed is:

1. A printed circuit board comprising:
a first connector pad comprising first and second input terminals;
a second connector pad comprising third and fourth input terminals;
first and second connection components; and
first, second, and third transmission lines;
a chip comprising a first output terminal connected to the first transmission line, a second output terminal connected to the second transmission line;
wherein upon a condition that a connector is installed on the first connector pad, the first transmission line is connected to the first input terminal via the first connection component, the second transmission line is connected to the third transmission line via the second connection component, and the third transmission line is connected to the second input terminal;
upon a condition that the connector is installed on the second connector pad, the first transmission line is connected to the third transmission line via the first connection component, the third transmission line is connected to the third input terminal, the second transmission line is connected to the fourth input terminal via the second connection component.

2. The printed circuit board as claimed in claim 1, further comprising a third connection component, upon a condition that the connector is installed on the first connector pad, a third connection component is connected between the third transmission line and the second input terminal.

3. The printed circuit board as claimed in claim 1, further comprising a third connection component, upon a condition that the connector is installed on the second connector pad, the third connection component is connected between the third transmission line and the third input terminal.

4. The printed circuit board as claimed in claim 2, wherein the third connection component is a zero ohm resistor.

5. The printed circuit board as claimed in claim 1, wherein the first and second connection components are capacitors.

6. The printed circuit board as claimed in claim 1, wherein the first and second connector pads are configured to be installed with different connectors.

7. A method for supporting two connectors on a printed circuit board, comprising: providing:
a first connector pad comprising first and second input terminals;
a second connector pad comprising third and fourth input terminals;
first and second connection components; and
first, second, and third transmission lines;
a chip comprising a first output terminal connected to the first transmission line, a second output terminal connected to the second transmission line;
upon a condition that a connector is installed on the first connector pad, connecting the first transmission line to the first input terminal via the first connection component, the second transmission line to the third transmission line via the second connection component, and the third transmission line to the second input terminal; and
upon a condition that another connector is installed on the second connector pad, connecting the first transmission line to the third transmission line via the first connection component, the third transmission line to the third input terminal, and the second transmission line to the fourth input terminal via the second connection component.

8. The method as claimed in claim 7, wherein further comprising, upon a condition that a connector is installed on the first connector pad, connecting a third connection component between the third transmission line and the second input terminal.

9. The method as claimed in claim 7, wherein further comprising, upon a condition that another connector is installed on the second connector pad, connecting a third connection component between the third transmission line and the third input terminal.

10. The method as claimed in claim 8, wherein the third connection component is a zero ohm resistor.

11. The method as claimed in claim 7, wherein the first and second connection components are capacitors.

12. The method as claimed in claim 7, wherein the first and second connector pads are configured to be installed with different connectors.
